(19) United States
(12) Patent Application Publication
(10) Pub. No.: US 2007/0215998 A1
(43) Pub. Date: Sep. 20, 2007

(54) LED package structure and method for manufacturing the same

(75) Inventors: Chen-Ze Hu, Zhonghe City (TW); Shen-Yin Tsai, Jen Te Hsian (TW); Chin-Ming Wang, Kaohsiung City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Chi Lin Technology Co., Ltd.

(21) Appl. No.: 11/385,178

(22) Filed: Mar. 20, 2006

(51) Int. Cl. H01L 23/02

(52) U.S. Cl. 257/678

(57) ABSTRACT

A LED package structure is disclosed. The LED package structure includes a substrate, a light emitting diode, a plasma chemical vapor deposition layer and a transparent material layer, wherein the substrate has a plurality of contacts. The light emitting diode is disposed on the substrate and electrically contacted to the contacts. The plasma chemical vapor deposition layer is disposed on the light emitting diode and the refractive index of the plasma chemical vapor deposition layer is smaller than that of the light emitting diode. The transparent material layer is disposed on the plasma chemical vapor deposition layer and the refractive index of the transparent material layer is smaller than that of the plasma chemical vapor deposition layer.

### FIELD OF THE INVENTION

The present invention relates to a LED package structure, and more particularly, to a LED package structure which can enhance the light extraction efficiency.

### BACKGROUND OF THE INVENTION

A LED (Light Emitting Diode) is a solid-state semiconductor device and a refractive index of its substrate is about 2.3 or near. In general, a LED package structure includes a LED chip with a refractive index about 2.5 on which p-electrode and n-electrode are connected to the substrate by using the method of wire bond or flip chip, and then a packaging resin made of transparent material with a refractive index of about 1.58 is used to package the LED chip. With regard to this type of LED package structure, because the difference between the refractive index of the substrate (about 2.5) and that of the transparent packaging resin (about 1.58) is too big, the light extraction efficiency of the LED package structure is merely about 5%, wherein most of the light is retained inside the LED chip, thus resulting in illumination loss and heat generation causes the degradation of LED performance.

For improving the above-mentioned problems, some conventional technologies are developed to implement various regular or irregular microstructures on the surface of the LED chip for roughening, thereby destroying the total internal reflection. However, with the application of these conventional methods, since the rough structure on the surface of the LED chip is difficult to be controlled, the efficiency and quality differences among the respective LED chips are quite a lot.

### SUMMARY OF THE INVENTION

Therefore, there is a need to develop an improved LED package structure and a method thereof for substantially resolving the problem that the light extraction efficiency of the conventional LED chip is too low.

Accordingly, one aspect of the present invention is to provide a LED package structure, which includes a plasma chemical vapor deposition layer with a single-layer or multiple-layer structure so as to substantially reduce the total internal reflection within the LED chip, thereby resolving the problem of the LED chip having too low light extraction efficiency.

The other aspect of the present invention is to provide a method for manufacturing the LED package structure, wherein a plasma chemical vapor deposition method is used to manufacture the LED package structure having plasma chemical vapor deposition layers with the single-layer or multiple-layer for enhancing the light extraction efficiency of the LED chip, thus promoting the performance of the LED chip.

According to an preferred embodiment of the present invention, the present invention provides a LED package structure comprising a substrate having a plurality of contacts, a LED disposed on the substrate, a plasma chemical vapor deposition layer disposed on the LED, and a transparent material layer disposed on the plasma chemical vapor deposition layer, wherein the LED is electrically connected to the contacts, and the refractive index of the plasma chemical vapor deposition layer is smaller than that of the LED, and the refractive index of the transparent material layer is smaller than that of the plasma chemical vapor deposition layer.

According to the other preferred embodiment of the present invention, the present invention provides a LED package structure comprising a substrate having a plurality of contacts, a plurality of LED chips disposed on the substrate, a plasma chemical vapor deposition layer disposed on the LED chips, and a transparent material layer disposed on the plasma chemical vapor deposition layer, wherein the LED chips are electrically connected to the contacts, and the refractive index of the plasma chemical vapor deposition layer is smaller than that of the LED chips, and the refractive index of the transparent material layer is smaller than that of the plasma chemical vapor deposition layer.

According to the preferred embodiment of the present invention, the aforementioned plasma chemical vapor deposition layer can be such as a transition metal oxide which has the refractive index in the range of about 1.7 to 2.6.

According to the preferred embodiment of the present invention, the aforementioned plasma chemical vapor deposition layer can be such as titanium oxide (TiO₂), tantalum oxide (Ta₂O₅), zirconium oxide (ZrO₂) or niobium oxide (Nb₂O₅).

With the application of the aforementioned LED package structure and the manufacturing method thereof, a single layer or multiple layers of plasma chemical vapor deposition layers with a gradually-decreasing refractive index is deposited on the LED chip by the plasma chemical vapor deposition method, so that the total internal reflection can be reduced for enhancing the light extraction efficiency of the LED chip. In comparison with the conventional structure and the manufacturing method thereof, the package structure and the manufacturing method thereof of the present invention not only are relative brief and more efficient, but also can precisely control the deposition of a single layer or multiple layers of the gradient-index plasma chemical vapor deposition layer on the LED chip.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIGS. 1A-1C are a series of cross-sectional schematic diagrams showing the process for manufacturing a LED package structure according to a preferred embodiment of the present invention; and

FIGS. 2A-2E are a series of cross-sectional schematic diagrams showing the process for manufacturing the other LED package structure according to a preferred embodiment of the present invention.

### DETAILED DESCRIPTION OF THE PREFERRED EMBODIMENT

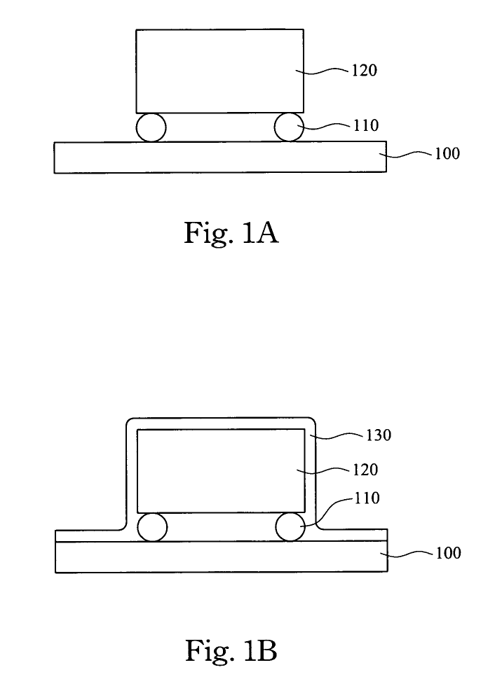

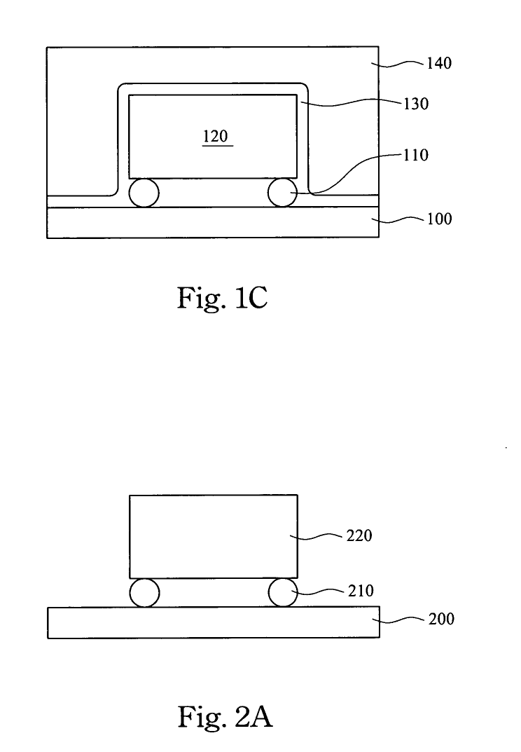

Referring FIG. 1A to FIG. 1C, FIG. 1A to FIG. 1C are a series of cross-sectional schematic diagrams showing the process for manufacturing a LED package structure according to a preferred embodiment of the present invention. At first, such as shown in FIG. 1A, a LED chip 120 with a refractive index between about 2.3 and about 4 is provided. In this embodiment, the LED chip 120 is a gallium nitride (GaN) with the refractive index of about 2.5. An anode electrode and a cathode electrode (not shown) located on the LED chip 120 are electrically connected to a substrate (e.g. a printed circuit board 100) having a plurality of contacts via solder bumps 110 by using a flip chip method. Alternatively, the LED chip 120 can be electrically connected to the printed circuit board 100 by wire bonding. Then, such as shown in FIG. 1B, a plasma chemical vapor deposition layer 130 is conformally formed on the LED chip 120, wherein the refractive index of the plasma chemical vapor deposition layer 130 is smaller than that of the LED chip 120. In this embodiment, the plasma chemical vapor deposition layer 130 is a single-layer structure, and its thickness is larger than about 20 nm. The refractive index of the plasma chemical vapor deposition layer 130 is between about 1.7 and about 2.6. In this embodiment, the refractive index of the plasma chemical vapor deposition layer 130 is about 2.1. Further, the plasma chemical vapor deposition layer 130 is formed by a plasma chemical vapor deposition method, and is made of a transition metal oxide such as titanium oxide (TiO₂), tantalum oxide (Ta₂O₅), zirconium oxide (ZrO₂) and niobium oxide (Nb₂O₅). The plasma chemical vapor deposition method is a true surface deposition process that can deposit the plasma chemical vapor deposition layer 130 with a thickness from few Å up to few μm onto the LED chip 120. In the plasma chemical vapor deposition method, monomer of high refractive index precursor is polyermized onto the surface of the LED chip 120. The monomer is activated by plasma into a gaseous complex, composed of electrons, ions, gas atoms, free radicals and molecules in an excited state, such state also known as the plasma state. The plasma state generates highly reactive free radicals, which can be uniformly diffused and deposited on the surface of the LED chip 120. As the LED chip 120 is exposed to the plasma, high refractive index precursor reacts with the mixing reactive gases and forms free radicals that are combined and form a high refractive index thin film coating on the surface of the LED chip 120. The thin film has uniform, highly crosslinked, stand for high temperature and amorphous in nature. Each individual layer thickness and the refractive index of the thin film can be calculated and controlled. Thereafter, such as shown in FIG. 1C, a transparent material layer 140 is formed on the plasma chemical vapor deposition layer 130 for forming the LED package structure, wherein the refractive index of the transparent material layer 140 is smaller than that of the plasma chemical vapor deposition layer 130. The refractive index of the transparent material layer 140 is between about 1.4 and about 1.7, and is made of UV curable heat-resistant resin, silicone or epoxy. In this embodiment, the refractive index of the transparent material layer 140 is about 1.58. According to this LED package structure of the present invention, the difference between the refractive index of the LED chip 120 and that of the plasma chemical vapor deposition layer 130 is about 0.4, and the difference between the refractive index of the plasma chemical vapor deposition layer 130 and that of the transparent material layer 140 is about 0.5. Because the difference between the refractive index of the LED chip 120 and that of the transparent material layer 140 can be lowered by adding the plasma chemical vapor deposition layer 130, the light extraction efficiency of the LED package structure can achieve about 11%, which is larger than the double of the light extraction efficiency of the conventional LED package structure (about 5%) without the plasma chemical vapor deposition layer 130. The LED package structure of the present invention is characterized in adding the plasma chemical vapor deposition layer 130 between the LED chip 120 and the transparent material layer 140, and because the refractive index of the plasma chemical vapor deposition layer 130 is between that of the LED chip 120 and that of the transparent material layer 140, the problem of the LED chip 120 having too low light extraction efficiency caused by the large difference between the refractive index of the LED chip 120 and that of the transparent material layer 140 can be prevented.

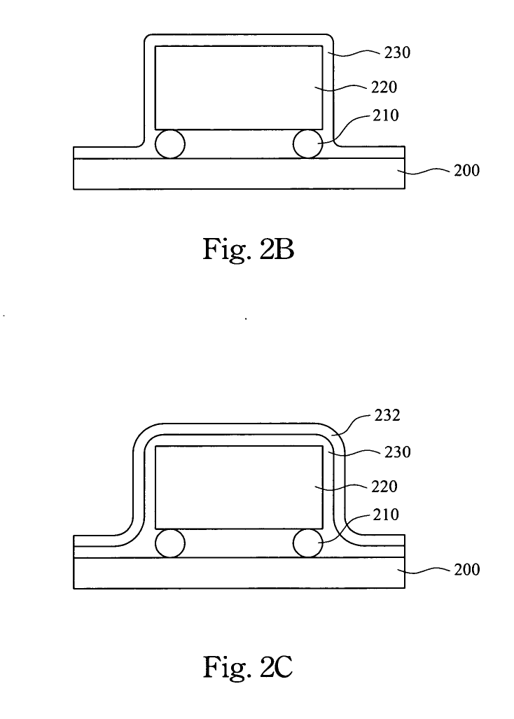

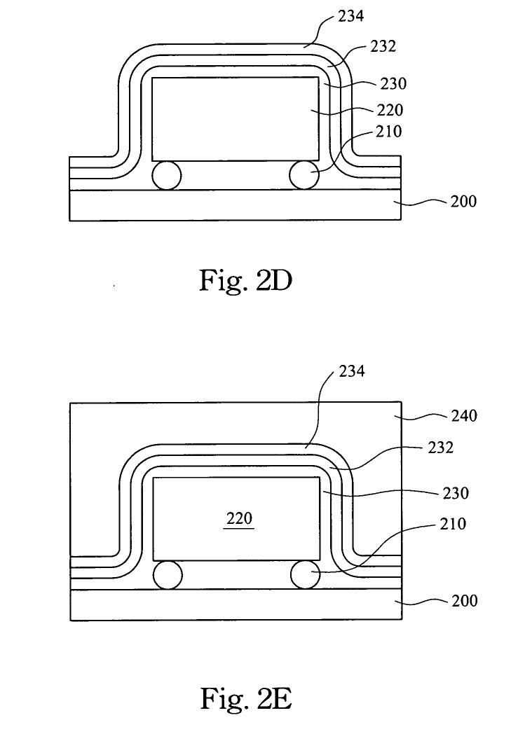

Referring to FIG. 2A to FIG. 2E, FIG. 2A to FIG. 2E are a series of cross-sectional schematic diagrams showing the process for manufacturing a LED package structure according to the other preferred embodiment of the present invention. At first, such as shown in FIG. 2A, a LED chip 220 with a refractive index between about 2.3 and about 4 is provided. In this embodiment, the LED chip 220 is a GaAs with the refractive index of about 3.6. An anode electrode and a cathode electrode (not shown) on the LED chip 220 are electrically connected to a printed circuit board 200 having a plurality of contacts via solder bumps 210 by using a flip chip method. Alternatively, the LED chip 220 is electrically connected to the printed circuit board 200 by wire bonding. Then, a process of forming a plasma chemical vapor deposition layer with a multiple-layers structure is performed. In this embodiment, such as shown in FIG. 2B, a first refractive index layer 230 is first conformally formed on the LED chip 220, wherein the refractive index of the first refractive index layer 230 is smaller than that of the LED chip 220. In this embodiment, the refractive index of the first refractive index layer 230 is between about 2.1 and about 2.6 and its thickness is larger than about 20 nm. Further, the first refractive index layer 230 is formed by a plasma chemical vapor deposition method and is made of a transition metal oxide such as TiO₂, Ta₂O₅, ZrO₂ and Nb₂O₅. Thereafter, such as shown in FIG. 2C, a second refractive index layer 232 is conformally formed on the first refractive index layer 230, wherein the refractive index of the second refractive index layer 232 is smaller than that of the first refractive index layer 230. In this embodiment, the refractive index of the second refractive index layer 232 is between about 1.7 and about 2.1, and its thickness is larger than about 20 nm. Additionally, the second refractive index layer 232 is formed by a plasma chemical vapor deposition method and is made of a transition metal oxide such as TiO₂, Ta₂O₅, ZrO₂ and Nb₂O₅. Then, such as shown in FIG. 2D, a third refractive index layer 234 is conformally formed on the second refractive index layer 232, wherein the refractive index of the third refractive index layer 234 is smaller than that of the second refractive index layer 232. In this embodiment, the refractive index of the third refractive index layer 234 is about 1.8 or 1.7 and its thickness is larger than about 20 nm. Further, the third refractive index layer 234 is formed by a plasma chemical vapor deposition method and, is made of a transition metal oxide, such as TiO₂, Ta₂O₅, ZrO₂ and Nb₂O₅. Thereafter, such as shown in FIG. 2E, a transparent material layer 240 is formed on the third refractive index layer 234 for forming the LED package structure, wherein a refractive index of the transparent material layer 240 is smaller than that of the third refractive index layer 234. In the embodiment, the refractive index of the transparent material layer 240 is between about 1.4 and about 1.7, and is made of UV curable heat-resistant resin, silicone or epoxy. The difference between the refractive index of the second refractive index layer 232 and that of the first refractive index layer 230 is between about 0.2 and about 0.6. The difference between the refractive index of the third refractive index layer 234 and that of the second refractive index layer 232 is between about 0.1 and about 0.4. Additionally, the first refractive index layer 230, the second refractive index layer 232 and the third refractive index layer 234 are formed by using the plasma chemical vapor deposition method, and their respective materials and thickness are similar to one another. Thus, in the present embodiment, the first refractive index layer 230, the second refractive index layer 232 and the third refractive index layer 234 can be regarded as one gradient-index plasma chemical vapor deposition layer, wherein the refractive index is gradually decreasing from the LED chip 220 to the transparent material layer 240. The LED package structure is characterized in adding the gradient-index plasma chemical vapor deposition layer between the LED chip 220 and the transparent material layer 240. Because the large difference between the refractive index of the LED chip 120 and that of the transparent material layer 140 is avoided, the problem of the LED chip 220 having too low light extraction efficiency is resolved. Besides, the gradient-index plasma chemical vapor deposition layer is formed by using the plasma chemical vapor deposition method, so that the plasma chemical vapor deposition layers with various refractive indices can be formed directly within the same working environment, wherein the plasma chemical vapor deposition method can precisely control the composition and thickness of the plasma chemical vapor deposition layer. Therefore, the manufacturing method of the present invention can not only simplify the process of depositing the plasma chemical vapor deposition layer, but also achieve much better efficacy of manufacturing the plasma chemical vapor deposition layer.

It is worthy to be noted that, in one process of manufacturing the LED package structure of the present invention, a wafer with a plurality of LED chips is first diced into individually separate chips, and then the chip is connected to a substrate by a wire bonding or flip chip method, and thereafter a plasma chemical vapor deposition layer is deposited on the LED chip by a plasma chemical vapor deposition method and a transparent material layer is deposited on the plasma chemical vapor deposition layer above the LED chip; and, alternatively, in another process of manufacturing the LED package structure of the present invention, a wafer with a plurality of LED chips is first electrically connected to the substrate by a wire bonding or flip chip method, and then the plasma chemical vapor deposition layer is deposited on the wafer by the plasma chemical vapor deposition method and the transparent material layer is deposited on the plasma chemical vapor deposition layer above the wafer, and thereafter the wafer can be diced into individual separate chips or just be kept as a whole without dicing. Similarly, in further another process of manufacturing the LED package structure of the present invention, the LED chips with different colors, such as with three primary colors of red, green and blue, can be first assembled to form a LED chip set, and then the LED chip set is electrically connected to a substrate by a wire bonding or flip chip method, and thereafter the plasma chemical vapor deposition layer is deposited on the LED chip set by the plasma chemical vapor deposition method and the transparent material layer is deposited on the plasma chemical vapor deposition layer above the LED chip set.

In general, the LED package structure of the present invention is featured in first depositing a single-layered or multiple-layered gradient-index plasma chemical vapor deposition layer on the LED chip; and then depositing the transparent material layer on the plasma chemical vapor deposition layer, thereby reducing the loss caused by the total internal reflection and increasing the light extraction efficiency of the LED chip. In comparison with the conventional structure and manufacturing method, the package structure and the manufacturing method thereof according to the present invention are briefer, and the plasma chemical vapor deposition method can precisely control the thickness and composition of the single-layered or multiple-layered plasma chemical vapor deposition layer on the LED chip.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structure.

What is claimed is:

1. A LED package structure, comprising:
a substrate having a plurality of contacts;
at least one LED disposed on said substrate, wherein said at least one LED is electrically connected to said contacts;
a plasma chemical vapor deposition layer disposed on said at least one LED, wherein the refractive index of said plasma chemical vapor deposition layer is smaller than the refractive index of said at least one LED; and
a transparent material layer disposed on said plasma chemical vapor deposition layer, wherein the refractive index of said transparent material layer is smaller than the refractive index of said plasma chemical vapor deposition layer.

2. The LED package structure of claim 1, wherein said at least one LED is one single LED chip or one single wafer including a plurality of LED chips.

3. The LED package structure of claim 1, wherein said at least one LED comprises a plurality of LED chips including a red LED chip, a green LED chip and a blue LED chip.

4. The LED package structure of claim 1, wherein said plasma chemical vapor deposition layer is made of a transition metal oxide.

5. The LED package structure of claim 1, wherein said plasma chemical vapor deposition layer is made of one single layer with a refractive index substantially between 1.7 and 2.6.

6. The LED package structure of claim 5, wherein a thickness of said plasma chemical vapor deposition layer is larger than 20 nm.

7. The LED package structure of claim 1, wherein said plasma chemical vapor deposition layer is a gradient-index layer of which the refractive index is gradually decreasing from said LED to said transparent material layer.

8. The LED package structure of claim 7, wherein said plasma chemical vapor deposition layer is a multiple-layer structure, said multiple-layer structure comprises:
a first refractive index layer disposed on said LED, wherein the refractive index of said first refractive index layer is smaller than the refractive index of said LED; and
a second refractive index layer disposed on said first refractive index layer, wherein the refractive index of said second refractive index layer is smaller than the refractive index of said first refractive index layer.

9. The LED package structure of claim 8, wherein a thickness of said first plasma chemical vapor deposition layer is larger than 20 nm.

10. The LED package structure of claim 8, wherein the refractive index of said first plasma chemical vapor deposition layer is substantially between 2.1 and 2.6.

11. The LED package structure of claim 8, wherein a thickness of said second plasma chemical vapor deposition layer is larger than 20 nm.

12. The LED package structure of claim 8, wherein the refractive index of said second plasma chemical vapor deposition layer is substantially between 1.7 and 2.1.

13. The LED package structure of claim 8, wherein the difference between the refractive index of said second plasma chemical vapor deposition layer and the refractive index of said first plasma chemical vapor deposition layer is substantially between 0.2 and 0.6.

14. The LED package structure of claim 8, further comprising:
a third refractive index layer disposed on said second plasma chemical vapor deposition layer, wherein the refractive index of said third plasma chemical vapor deposition layer is smaller than the refractive index of said second plasma chemical vapor deposition layer.

15. The LED package structure of claim 14, wherein a thickness of said third plasma chemical vapor deposition layer is larger than 20 nm.

16. The LED package structure of claim 14, wherein the refractive index of said third plasma chemical vapor deposition layer is substantially 1.7 or 1.8.

17. The LED package structure of claim 14, wherein the difference between the refractive index of said third plasma chemical vapor deposition layer and the refractive index of said second plasma chemical vapor deposition layer is substantially between 0.1 and 0.4.

18. A method for manufacturing a LED package structure, said method comprising:
providing a substrate having a plurality of contacts;
disposing at least one LED on said substrate, wherein said at least one LED is electrically connected to said contacts;
conformally forming a plasma chemical vapor deposition layer on said at least one LED by a plasma chemical vapor deposition method, wherein the refractive index of said plasma chemical vapor deposition layer is smaller than the refractive index of said at least one LED; and
forming a transparent material layer on said plasma chemical vapor deposition layer, wherein the refractive index of said transparent material layer is smaller than the refractive index of said plasma chemical vapor deposition layer.

19. The method of claim 18, wherein said plasma chemical vapor deposition layer is made of one single layer with a refractive index substantially between 1.7 and 2.6.

20. The method of claim 18, wherein said plasma chemical vapor deposition layer is made of a transition metal oxide.

21. The method of claim 18, wherein said plasma chemical vapor deposition layer has a gradient—index of which the refractive index is gradually decreasing from said LED to said transparent material layer.

22. The method of claim 18, wherein the step of forming said plasma chemical vapor deposition layer on said LED comprises:
forming a first refractive index layer on said LED, wherein the refractive index of said first refractive index layer is smaller than the refractive index of said at least one LED; and
forming a second refractive index layer on said first refractive index layer, wherein the refractive index of said second refractive index layer is smaller than the refractive index of said first refractive index layer.

23. The method of claim 22, wherein the refractive index of said first plasma chemical vapor deposition layer is substantially between 2.1 and 2.6.

24. The method of claim 22, wherein the refractive index of said second plasma chemical vapor deposition layer is substantially between 1.7 and 2.1.

25. The method of claim 22, wherein the difference between the refractive index of said second plasma chemical vapor deposition layer and the refractive index of said first plasma chemical vapor deposition layer is substantially between 0.2 and 0.6.

26. The method of claim 22, further comprising:
forming a third refractive index layer on said second plasma chemical vapor deposition layer, wherein the refractive index of said third refractive index layer is smaller than the refractive index of said second plasma chemical vapor deposition layer.

27. The method of claim 26, wherein the refractive index of said third plasma chemical vapor deposition layer is substantially 1.7 or 1.8.

28. The method of claim 26, wherein the difference between the refractive index of said third plasma chemical vapor deposition layer and the refractive index of said second plasma chemical vapor deposition layer is substantially between 0.1 and 0.4.
